(19) United States
(12) Patent Application Publication
(10) Pub. No.: US 2015/0137165 A1
(43) Pub. Date: May 21, 2015

(54) LIGHT-EMITTING DEVICE

(71) Applicant: PANASONIC INTELLECTUAL PROPERTY MANAGEMENT CO., LTD., Osaka (JP)

(72) Inventors: Naoki TAGAMI, Osaka (JP); Toshiaki KURACHI, Kyoto (JP)

(73) Assignee: PANASONIC INTELLECTUAL PROPERTY MANAGEMENT CO., LTD., Osaka (JP)

(21) Appl. No.: 14/546,326

(22) Filed: Nov. 18, 2014

(30) Foreign Application Priority Data
Nov. 21, 2013 (JP) 2013-241058

(51) Int. Cl. H01L 33/56; H01L 33/64; H01L 33/50

(52) U.S. Cl. CPC H01L 33/56; H01L 33/50; H01L 33/641
USPC 257/98

(57) ABSTRACT

A light-emitting device includes a mounting board, a light-emitting element mounted on a main face of the mounting board, and a sealing member covering the light-emitting element. The sealing member includes a first sealing layer covering a part of the main face of the mounting board and the light-emitting element, and a second sealing layer covering the first sealing layer. The first sealing layer includes particles containing at least one material selected from a group consisting of cerium oxide, titanium oxide, iron oxide, and carbon, and silicone resin. The second sealing layer includes phosphor particles for converting a part of light emitted from light-emitting element into a long wavelength light and radiating it, and silicone resin.

### BACKGROUND OF THE INVENTION

1. Field of the Invention

The disclosure relates to light-emitting devices equipped with light-emitting element, such as a light-emitting diode (LED) and laser diode (LD).

2. Background Art

LED device 151 shown in FIG. 6 is disclosed in U.S. Pat. No. 4,980,492, for example, as a light-emitting device.

LED device 151 includes support 123, LED chip 114, and LED sealing resin 117. LED sealing resin 117 includes silicone resin 112 and composite 113 of a heat resistance material and phosphor.

### SUMMARY OF THE INVENTION

A light-emitting device in the disclosure includes a mounting board, a light-emitting element mounted on a main face of the mounting board, and a sealing member covering the light-emitting element. The sealing member includes a first sealing layer covering a part of the main face of the mounting board and the light-emitting element, and a second sealing layer covering the first sealing layer. The first sealing layer includes particles containing at least one material selected from a group consisting of cerium oxide (C₂O₂), titanium oxide (TiO₂), iron oxide, and carbon, and silicone resin. The second sealing layer includes silicone resin and phosphor particles for converting a part of light emitted from light-emitting element 3 into a long wavelength light and radiating it.

The light-emitting device as configured above can improve heat resistance and light extraction efficiency.

### BRIEF DESCRIPTION OF THE DRAWINGS

FIG. 1 is a schematic sectional view of a light-emitting device in an exemplary embodiment.

FIG. 2 is a schematic plan view of the light-emitting device in the exemplary embodiment.

FIG. 3 is a schematic sectional view of a first modified example of the light-emitting device in the exemplary embodiment.

FIG. 4 is a schematic sectional view of a second modified example of the light-emitting device in the exemplary embodiment.

FIG. 5 is a schematic sectional view of a third modified example of the light-emitting device in the exemplary embodiment.

FIG. 6 is a schematic sectional view of a conventional light-emitting device.

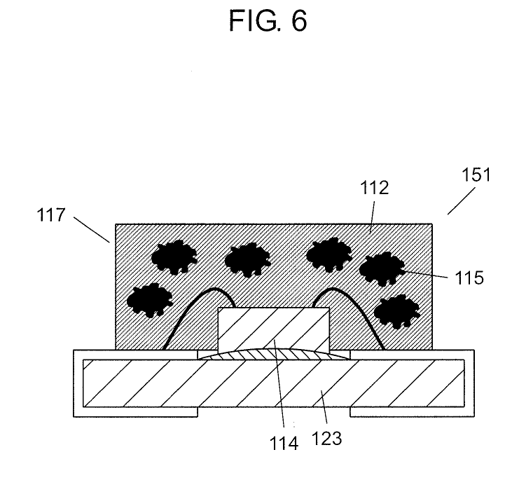

### DETAILED DESCRIPTION OF PREFERRED EMBODIMENTS

A light-emitting device in an exemplary embodiment of the disclosure is described with reference to drawings. It is apparent that the exemplary embodiment described below is a preferred embodiment and thus values, shapes, materials, components, positions or connection of the components, processes, and process sequence are just examples. It does not limit the disclosure in any way.

Each drawing is a schematic diagram, and thus it is not precisely illustrated. In the drawings, a same reference mark is given to a practically same component to omit duplicate description or simplify description.

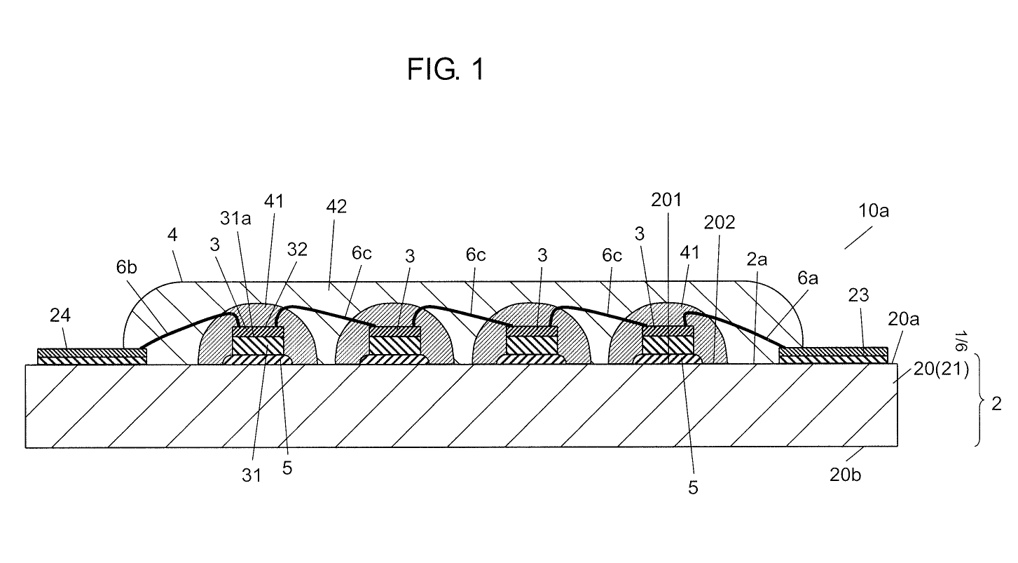

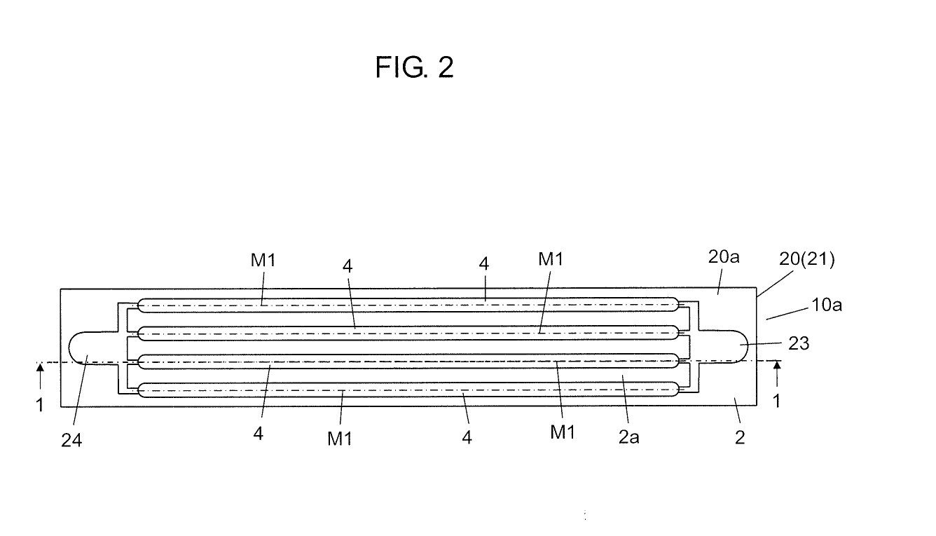

Light-emitting device 10a in the exemplary embodiment is described below with reference to FIG. 1 and FIG. 2.

Light-emitting device 10a includes mounting board 2, light-emitting element 3 mounted on main face 2a of mounting board 2, and sealing member 4 covering light-emitting element 3. Sealing member 4 includes first sealing layer 41 covering a part of main face 2a of mounting board 2 and light-emitting element 3, and second sealing layer 42 covering first sealing layer 41. First sealing layer 41 includes particles containing at least one material selected from a group consisting of cerium oxide (C₂O₂), titanium oxide (TiO₂), iron oxide, and carbon, and silicone resin. Second sealing layer 42 includes phosphor particles for converting a part of light emitted from light-emitting element 3 into a long-wavelength light and radiating it, and silicone resin.

Light-emitting element 3 is an LED. Light-emitting element 3 includes substrate 31, and multi-layer film 32 formed of semiconductor material on main face 31a of substrate 31.

Substrate 31 supports multilayer film 32. Multilayer film 32 can be formed typically by epitaxial growth method. Multilayer film 32 includes a light-emitting layer (not illustrated).

Light-emitting element 3 is a blue LED that emits a blue light. In light-emitting element 3, for example, a GaN substrate can be adopted for substrate 31. As a semiconductor material of multilayer film 32, for example, a GaN material can be adopted. In addition to the GaN substrate, a sapphire substrate, for example, can be adopted as substrate 31. Light-emitting element 3 can be, for example, a purple LED that emits a purple light, in addition to the blue LED.

In light-emitting element 3, a first electrode and a second electrode are provided on one face of light emitting element 3.

The size of light-emitting element 3 is, for example, 0.52 mm×0.39 mm when its plan view is rectangular. When its plan view is square, the size of light-emitting element 3 is, for example, 0.3 mm×0.3 mm, 0.45 mm×0.45 mm, or 1 mm×1 mm. The plan view shape and size of light-emitting element 3 are not limited.

Light-emitting element 3 is mounted on mounting board 2. By mounting, light-emitting element 3 is mechanically and also electrically connected to mounting board 2.

Mounting board 2 includes support 20 and first conductor 23 and second conductor 24 formed in predetermined patterns on main face 20a of support 20. Light-emitting element 3 and first conductor 23 and second conductor 24 are electrically connected. Mounting board 2 is formed such that first conductor 23 and second conductor 24 can be electrically separated. First conductor 23 and second conductor 24 are, for example, configured with a laminated film of Ni film and Au film. Support 20 is preferably configured with ceramic substrate 21. Compared to the case of support 20 being configured with a resin substrate, support 20 configured with ceramic substrate 21 can improve heat dissipation of light-emitting device 10a, and thus light output can be increased.

In light-emitting device 10a, light-emitting element 3 is bonded to mounting board 2 via bonding part 5. This makes light-emitting element 3 mechanically connected to mounting board 2. A material of bonding part 5 preferably has a high transmittance of light emitted from light-emitting element 3. For example, silicone resin, epoxy resin, or a hybrid material of silicone resin and epoxy resin can be adopted. This allows bonding part 5 to transmit light emitted from light-emitting element 3.

In light-emitting device 10a, light-emitting element 3 is bonded to a placement area of light-emitting element 3 on support 20 via bonding part 5.

Ceramic substrate 21 configuring support 20 is formed of a flat sheet. Ceramic substrate 21 has light diffusion permeability, and transmits and diffuses light emitted from light-emitting element 3. As a material of ceramic substrate 21, for example, translucent ceramics can be adopted. As translucent ceramics, for example, alumina ceramics can be adopted. Translucent ceramics enables to adjust transmittance, reflectivity, refractive index, and heat conductivity by type and concentration of binder and other additives.

In light-emitting device 10a, ceramic substrate 21 preferably has light diffusion characteristics. Light emitted from light-emitting element 3 onto ceramic substrate 21 is diffused in ceramic substrate 21. This can suppress the light emitted from light-emitting element 3 onto ceramic substrate 21 from returning to light-emitting element 3. In addition, it becomes easier to extract light from projection area 201 of light-emitting element 3 on main face 20a of support 20 and its surrounding area 202. Accordingly, light extraction efficiency improves and thus total luminous flux also improves in light-emitting device 10a. The projection area of light-emitting element 3 on main face 20a of support 20 is an area that projects light-emitting element 3 in the thickness direction of light-emitting element 3 on main face 20a of support 20. Light emitted from light-emitting element 3 in surrounding area 202 on main face 20a of support 20 is emitted to a part where first conductor 23 and second conductor 24 are not formed. Mounting board 2 may have a reflective layer (not illustrated) for reflecting light from light-emitting element 3 on second face 20b of support 20 configured with ceramic substrate 21. In addition, in light-emitting device 10a, a reflective member (not illustrated) for reflecting light from light-emitting element 3 may be provided on second face 20b of mounting board 2. The reflective layer and reflective member are preferably formed in an area broader than a vertical projection area of sealing member 4 on second face 20b of support 20 configured with ceramic substrate 21. This enables to suppress color unevenness by suppressing the light emitted from light-emitting element 3 that does not pass through sealing member 4. Color unevenness is the state that chromaticity differs by the optical irradiation direction. With respect to heat dissipation, the reflective layer and reflective member are preferably formed of metal. Also with respect to heat dissipation, the reflective layer and reflective member are preferably formed in a further broader area. This enables to transfer heat generated in light-emitting element 3 and transferred to the reflective layer and reflective member to a further broader area. Accordingly, heat dissipation can be further improved.

Ceramic substrate 21 can be formed, for example, by sintering alumina particles. A particle size of alumina particles is about 0.6 μm. The particle size of alumina particles is preferably in a range between 0.5 μm and 5 μm. As the particle size of alumina particles becomes larger, the reflectivity of ceramic substrate 21 decreases. As the particle size of alumina particles becomes smaller, the light scattering effect tends to increase. Lower reflectivity and higher scattering effect are in the trade-off relation.

The particle size in the above description is a value obtained from a particle size distribution curve based on the number of particles. The particle size distribution curve based on the number of particles is obtained by measuring particle size distribution using a picture imaging method. More specifically, this is obtained by the particle size (two-axis average diameter) gained by image processing of a picture taken by the scanning electron microscope (SEM), and the number of particles.

In mounting board 2, first conductor 23 and second conductor 24 are formed on ceramic substrate 21 typically by thin-film formation technology or plating technology.

The shape of mounting board 2 in a plan view is rectangular. However, the shape of mounting board 2 is not limited to rectangular. For example, it may be a multangular shape other than rectangular or round.

Light-emitting device 10a preferably has multiple light-emitting elements 3 on main face 2a of mounting board 2. This can improve the light output from light-emitting device 10a. Light-emitting elements 3 are aligned on mounting board 2 in arrays. FIG. 2 is a schematic plan view of light-emitting device 10a. FIG. 1 is a schematic sectional view of a cross-section taken along line 1-1 in FIG. 2.

In light-emitting device 10a, a group of light-emitting elements 3 connected in series in light-emitting elements 3 is disposed on virtual line M1 connecting first conductor 23 and second conductor 24. A first electrode of light-emitting element 3 closest to first conductor 23 on virtual line M is electrically connected to first conductor 23 by first wire 6a. A second electrode of light-emitting element 3 closest to second conductor 24 on virtual line M1 is electrically connected to second conductor 24 by second wire 6b. In adjacent light-emitting elements 3 on virtual line M1, the first electrode of one light-emitting element 3 is electrically connected to the second electrode of the other light-emitting element 3 by third wire 6c. This suppresses losses of light at first conductor 23 and second conductor 24, compared to the case that first conductor 23 and second conductor 24 exist near each of light-emitting elements 3. As a result, the light extraction efficiency of light-emitting device 10a can be improved. The losses of light include a loss due to absorption of light in first conductor 23 and second conductor 24. For example, a gold wire or aluminum wire can be adopted as first wire 6a, second wire 6b, and third wire 6c.

Light-emitting device 10a has multiple virtual lines M1. On each virtual line M1, four light-emitting elements 3 are disposed as a group of light-emitting elements 3. In an example shown in FIG. 2, there are four virtual lines M1. However, the number of virtual lines M1 or the number of light-emitting elements 3 on each virtual line M1 is not limited. In light-emitting element 10a, light-emitting elements 3 have series-parallel connection, but this is also not limited. For example, light-emitting elements may be connected in series, or light-emitting elements 3 may be connected in parallel, as long as mounting board 2 has first conductor 23 and second conductor 24 formed in a predetermined pattern based on a predetermined connection style of light-emitting elements 3.

In light-emitting device 10a, sealing member 4 is preferably formed linearly so as to cover the group of light-emitting elements 3 disposed on virtual line M1, first wire 6a, second wire 6b, and third wire 6c. Sealing member 4 covers light-emitting elements 3 disposed on virtual line M1, first wire 6a, second wire 6b, and third wire 6c in a straight line. This can suppress occurrence of disconnection in first wire 6a, second wire 6b, or third wire 6c. As a result, reliability of light-emitting device 10a can be improved.

In light-emitting device 10a, sealing member 4 may have, for example, a semicircular columnar shape. Semicircular columnar sealing member 4 can improve the light extraction efficiency and suppress color unevenness. Sealing member 4 has multiple first sealing layers 41 and one second sealing layer 42. First sealing layers 41 are preferably formed in a semispherical shape, and second sealing layer 42 is preferably formed in a semicircular columnar shape. Compared to a structure of configuring one sealing member 4 covering light-emitting elements 3 with one first sealing layer and one second sealing layer, the light extraction efficiency can be improved and color unevenness can also be suppressed.

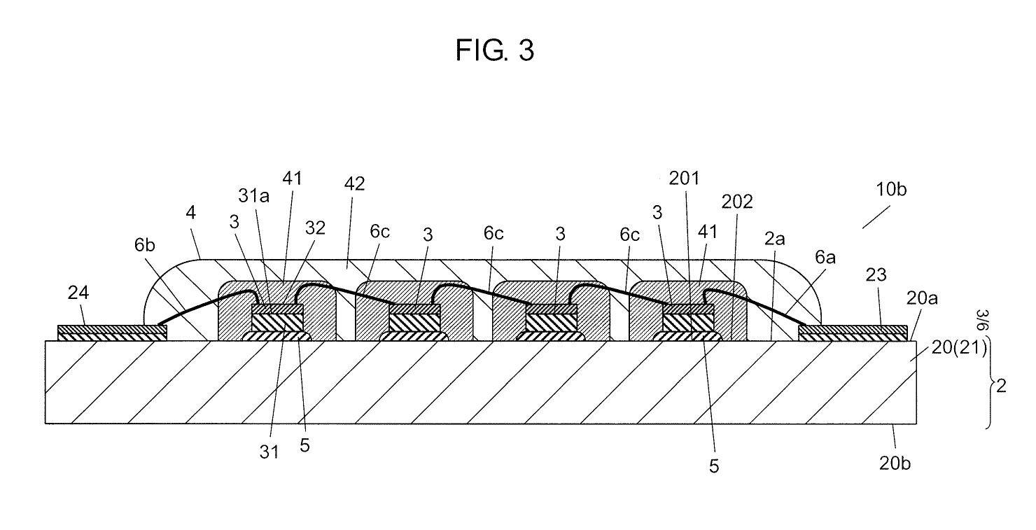

In light-emitting device 10a, first sealing layer 41 is preferably formed in a semispherical shape even if there is only one light-emitting element 3. This can suppress color unevenness, compared to light-emitting device 10b in a first modified example shown in FIG. 3 in which first sealing layer 1 is formed in a rectangular parallelepiped shape. As a shape of the surface of sealing member 4, an incident angle of light emitted from light-emitting element 3 on the surface of sealing member 4 is preferably smaller than the critical angle. The above incident angle is preferably smaller than the critical angle on substantially the entire surface of sealing member 4. For this purpose, sealing member 4 is preferably formed, for example in a semispherical shape. An optical axis of light-emitting element 3 and an optical axis of cylindrical lens sealing member 4 preferably match. This can suppress total reflection on the surface of sealing member 4 (a boundary face between sealing member 4 and air). In addition, since a light path length from light-emitting element 3 to the surface of sealing member 4 becomes substantially equalized, regardless of the direction of light emitted from light-emitting element 3, color unevenness can be further suppressed. The shape of sealing member 4 is not limited to a semispherical shape. For example, it may have a semi-elliptical shape.

In light-emitting device 10a, first conductor 23 and second conductor 24 have a comb shape, and they are disposed facing each other. However, shapes of first conductor 23 and second conductor 24 are not particularly limited. In addition, virtual line M1 is not limited to a straight line. It may be a curve or a combination of a straight line and curve.

First sealing layer 41 is formed of, as described above, a mixture of silicone resin and cerium oxide particles. First sealing layer 41 is formed of particles containing at least one material selected from a group consisting of cerium oxide, titanium oxide, iron oxide, and carbon, and silicone resin. In first sealing layer 41, particles containing at least one material selected from the group consisting of cerium oxide, titanium oxide, iron oxide and carbon are dispersed in a transparent layer formed of silicone resin. As carbon, for example, carbon black or black lead can be adopted. Content of the particles containing at least one material selected from the group consisting of cerium oxide, titanium oxide, iron oxide, and carbon is preferably more than 0 wt % and 1 wt % or less. This can suppress reduction of light transmittance of first sealing layer 41 in light-emitting device 10a. First sealing layer 41 is not limited to one type of particles containing at least one material selected from the group consisting of cerium oxide, titanium oxide, iron oxide, and carbon. It may contain multiple types. For example, first sealing layer 41 may be formed of a mixture of silicone resin, particles of cerium oxide, and particles of titanium oxide.

Second sealing layer 42 is, as described above, formed of a mixture of silicone resin and phosphor particles that convert a part of light emitted from light-emitting element 3 into a long-wavelength light and radiate it. The phosphor particles are excited by light emitted from light-emitting element 3, and radiate light with color different from that of light from light-emitting element 3. This enables light-emitting device 10a to emit a mixed-color light of light emitted from light-emitting element 3 and light emitted from the phosphor particles. For example, light-emitting device 10a may adopt a blue LED chip as light-emitting element 3, and yellow phosphor particles as the phosphor particles to obtain white light. More specifically, a blue light emitted from light-emitting element 3 and a yellow light emitted from yellow phosphor particles are emitted from sealing member 4 to generate a white light.

As the phosphor particles, for example, yellow phosphor particles and red phosphor particles may be adopted without limiting only to yellow phosphor particles. As the yellow phosphor particles, for example, Ce³⁺ activated YAG (Yttrium Aluminum Garnet) phosphor particles or Eu²⁺ activated oxynitride phosphor particles can be adopted. An example of Ce³⁺ activated YAG phosphors is Y₃Al₅O₁₂:Ce³⁺. An example of Eu²⁺ activated oxynitride phosphors is SrSi₂O₂N₂:Eu²⁺. As red phosphor particles, for example, Eu²⁺ activated nitride phosphor particles can be adopted. Examples of Eu²⁺ activated nitride phosphors are (Sr, Ca) AlSiN₃:Eu²⁺ and CaAlSiN₃:Eu²⁺.

Phosphor particles are not limited to one type of yellow phosphor particles. Two types of yellow phosphor particles with different light-emitting peak wavelengths may be adopted. Light-emitting device 10a can increase color rendering properties by adopting multiple types of phosphor particles as wavelength converting materials. In addition, red phosphor particles or green phosphor particles may be adopted as the phosphor particles. As green phosphor particles, for example, phosphor particles with composition of CaSc₂O₄:Ce³⁺, Ca₃Sc₂Si₃O₁₂:Ce³⁺, (Ca, Sr, Ba) Al₂O₄:Eu²⁺, or SrGa₂S₄:Eu²⁺ can be adopted as the phosphor particles.

The average particle size of phosphor particles is, for example, preferably in a range of 1 μm or more and 10 μm or less. As the average particle size of phosphor particles increases, a defect density decreases. As a result, an energy loss decreases and luminance efficiency increases. Therefore, with respect to the luminance efficiency, the average particle size is preferably 5 μm or more.

In second sealing layer 42, the content of phosphor particles is, for example, preferably in a range of 3 wt % or more and 50 wt % or less.

As silicone resin of first sealing layer 41 and second sealing layer 42, for example, thermosetting silicone resin, two-liquid curing silicone resin, or light-curing silicone resin can be adopted.

To manufacture light-emitting device 10A, mounting board 2 is first prepared. Then, the following first process, second process, and third process are executed sequentially. In the first process, light-emitting element 3, which is a die, is bonded onto main face 2a of mounting board 2 via bonding part 5, typically using a die-bonder. In the second process, first wire 6a, second wire 6b, and third wire 6c are formed, typically using a wire-bonder. In the third process, sealing member 4 is formed typically using a dispenser system. In this third process, first sealing layer 41 is first formed, and then second sealing layer 42 is formed.

For example, on forming first sealing layer 41 using the dispenser system, a dispenser head is moved along the alignment direction of light-emitting elements 3 to a position vertically above light-emitting element 3, and then a material of first sealing layer 41 is dispensed from a nozzle and applied. The material of first sealing layer 41 is silicone resin in which particles of a material selected from the group consisting of cerium oxide, titanium oxide, iron oxide, and carbon is kneaded.

In light-emitting device 10a, the average particle size of particles of a material selected from the group consisting of cerium oxide, titanium oxide, iron oxide, and carbon is preferably 10 μm or less. When the average particle size of the particles is 10 μm or more, the particles tend to settle out on applying the material of first sealing layer 41 to cover light-emitting elements 3, using the dispenser system. However, when the average particle size of the particles is 10 μm or less, dispersibility can be improved. Still more, the average particle size of the particles of a material selected from the group consisting of cerium oxide, titanium oxide, iron oxide, and carbon is preferably 1 μm or more. The average particle size of the particles is the average particle size measured on the volumetric basis using the dynamic light scattering method.

On forming second sealing layer 42, using the dispenser system, for example, a material of second sealing layer 42 is dispensed from the nozzle for application while the dispenser head is moved in the alignment direction of light-emitting element 3. The material of second sealing layer 42 is silicone resin in which phosphor particles are kneaded.

To apply the material of second sealing layer 42, the material is dispensed, for example, while the dispenser head is moved.

The dispenser system preferably includes a transfer mechanism for moving the dispenser head, a sensor for measuring heights from tables of main face 2a of mounting board 2 and the nozzle, and a controller for controlling the transfer mechanism and an amount of material dispensed from the nozzle. The transfer mechanism can be, for example, configured with a robot. The controller can be, for example realized by installing an appropriate program in a microcomputer. The dispenser system can support multiple models with different alignment of light-emitting elements 3, different number of light-emitting elements 3, or different line widths of second sealing layer 42 by changing the program installed in the controller as required.

The surface shape of second sealing layer 42 formed using the dispenser system can also be controlled, for example, by adjusting viscosity of the material. A curvature of the surface (convex curve) of second sealing layer 42 can be designed by viscosity or surface tension of the material of second sealing layer 42, or heights of first wire 6a, second wire 6b, and third wire 6c. The curvature can be increased, for example, by increasing viscosity or surface tension of the material, or increasing the heights of first wire 6a, second wire 6b, and third wire 6c. The width (line width) of linear second sealing layer 42 can be narrowed by increasing viscosity or surface tension of the material. Viscosity of the material of second sealing layer 42 is preferably set to a range roughly between 100 and 2000 mPa·s. For example, a viscosity value measured at normal temperature using a conical/planar rotational viscosimeter can be adopted as viscosity.

Still more, the dispenser system may include a heater for heating uncured material to achieve a required viscosity. This improves reproducibility of material application shape in the dispenser system. As a result, reproducibility of the surface shape of each of first sealing layer 41 and second sealing layer 42 can be improved.

In light-emitting device 10a, sealing member 4 includes first sealing layer 41 and second sealing layer 42. First sealing layer 41 directly covering light-emitting elements 3 is formed of a mixture of particles containing at least one material selected from the group consisting of cerium oxide, titanium oxide, iron oxide, and carbon, and silicone resin. This can suppress generation of a crack on sealing member 4 due to heat generation from light-emitting element 3. Heat resistance can thus be improved.

An estimation mechanism of improving heat resistance is a following mechanism in which particles, such as of cerium oxide, improve heat resistance of silicone resin. Heat generated in light-emitting element 3 generates radicals in silicone resin that become a cause of oxidation reaction of silicone resin. However, since ions contained in particles are reduced by reacting with radicals, it would appear that curing and degradation due to oxidation of silicone resin can be suppressed. For example, if the particles are cerium oxide, ions contained in the particles are cerium ions. Another estimation mechanism may also exist.

In light-emitting device 10a, second sealing layer 42 is formed of a mixture of phosphor particles for converting a part of light emitted from light-emitting element 3 into long-wavelength light and radiating it, and silicone resin. This can increase transmittance of light from sealing member 4, compared to the structure of dispersing particles containing at least one material selected from the group consisting of cerium oxide, titanium oxide, iron oxide, and carbon on the entire sealing member 4. Accordingly, the light extraction efficiency improves in light-emitting device 10a.

In light-emitting device 10a, bonding part 5 may be formed of a mixture of particles containing at least one material selected from the group consisting of cerium oxide, titanium oxide, iron oxide, and carbon, and silicone resin. This improves heat resistance of bonding part 5, and thus generation of a crack on bonding part 5 can be suppressed. As a result, reliability of light-emitting device 10a can be further improved. The average particle size of particles of a material selected from the group consisting of cerium oxide, titanium oxide, iron oxide, and carbon is preferably 10 μm or less. Still more, the average particle size of particles is preferably 1 μm or more. In bonding part 5, content of the particles containing at least one material selected from the group consisting of cerium oxide, titanium oxide, iron oxide, and carbon is preferably over 0 wt % and 1 wt % or less. This can suppress excessive decrease of light transmittance of bonding part 5.

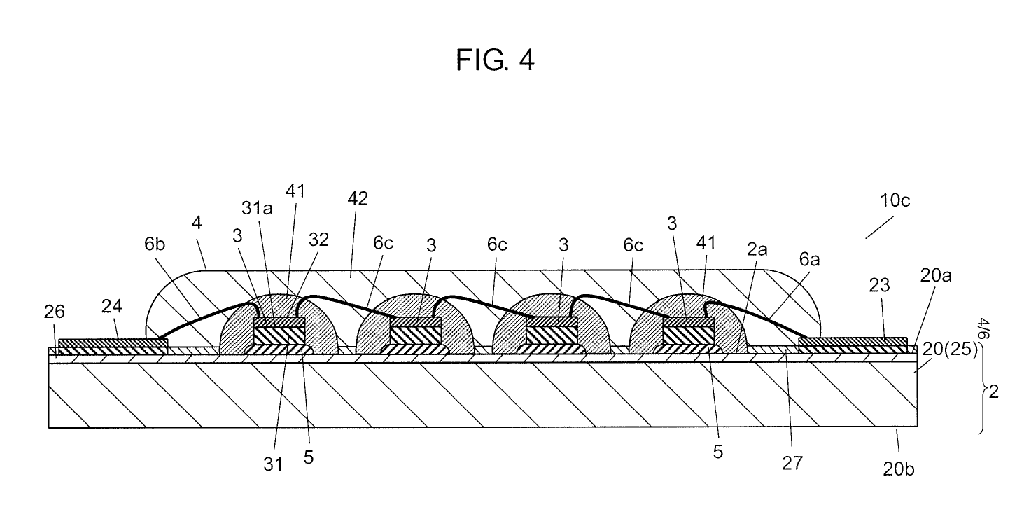

FIG. 4 is a schematic sectional view of light-emitting device 10c, which is a second modified example of light-emitting device 10a. The basic structure of light-emitting device 10c is roughly same as light-emitting device 10a. Light-emitting device 10c differs from light-emitting device 10a with respect to a point that support 20 in mounting board 2 is configured with metal substrate 25. In light-emitting device 10c, components same as that of light-emitting device 10a are given the same reference marks as that of light-emitting device 10a to omit duplicate description.

As metal substrate 25, for example, an aluminum substrate or copper substrate can be adopted. Electric insulation layer 26 is formed on the surface of metal substrate 25 that is support 20. In mounting board 2, first conductor 23 and second conductor 24 are formed on electric insulation layer 26. Mounting board 2 can be, for example, formed of a metal-base printed circuit board.

In light-emitting device 10c, mounting board 2 includes support 20, and first conductor 23 and second conductor 24 formed in predetermined patterns on main face 20a of support 20 and electrically connected to light-emitting elements 3. Support 20 is configured with metal substrate 25. This improves heat dissipation and thus reliability of light-emitting device 10c, compared to the case of using a resin substrate as support 20. Still more, light output of light-emitting device 10c can be improved.

In light-emitting device 10c, mounting board 2 includes white resist layer 27. Resist layer 27 preferably covers a portion of electric insulation layer 26 where none of first sealing layer 41, first conductor 23, and second conductor 24 is formed. For example, white resist can be adopted as a material of resist layer 27. An example of white resist is resin containing white pigment. Examples of white pigment are barium sulfate (BaSO₄) and titanium dioxide (TiO₂). An example of resin is silicone resin.

Light-emitting device 10c can more easily reflect light entering mounting board 2 from light-emitting element 3 on the surface of resist layer r27 because it includes white resist layer 27. This can thus suppress absorption of light emitted from light-emitting element 3 by mounting board 2. Accordingly, light extraction efficiency improves and light output thus improves in light-emitting device 10c.

In light-emitting device 10c, light-emitting element 3 may be bonded to metal substrate 25 via bonding part 5. This establishes a heat transfer path for transferring heat generated in light-emitting element 3 to metal substrate 25 without passing electric insulation layer 26 as a heat transfer path of heat generated in light-emitting element 3 in light-emitting device 10c. Accordingly, heat dissipation of light-emitting device 10c can be improved.

In light-emitting device 10c, light-emitting element 3 may be installed on metal substrate 25 via a sheet-like sub-mount member (not illustrated). A material of the sub-mount member preferably has heat conductivity higher than that of electric insulation layer 26 and smaller difference in linear expansion rate with light-emitting element 3 than that with metal substrate 25. This enables to transfer heat generated in light-emitting element 3 to the sub-mount member and metal substrate 25 without passing electric insulation layer 26. Accordingly, heat dissipation of light-emitting device 10c can be improved. As a material of sub-mount member, for example, aluminum nitride can be adopted. The sub-mount member and metal substrate 25 can be bonded via a bonding part. As a material of the bonding part for bonding the sub-mount member and metal substrate 25, for example, lead-free solder, such as AuSn and SnAGCu, is preferable. When AuSn is adopted as a material for the bonding part for bonding the sub-mount member and metal substrate 25, pre-treatment is required for forming a metal layer of Au or Ag in advance on a bonding face on the surface of metal substrate 25.

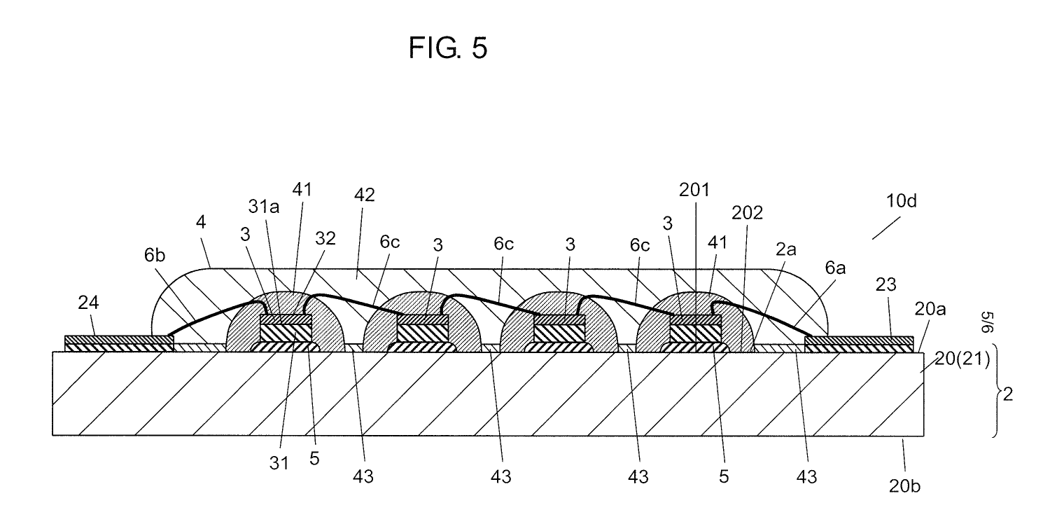

FIG. 5 is a schematic sectional view of light-emitting device 10d, which is a third modified example of light-emitting device 10a. The basic structure of light-emitting device 10d is roughly same as that of light-emitting device 10a, but a structure of sealing member 4 is different. In light-emitting device 10d, same reference marks are given to components same as that of light-emitting device 10a to omit duplicate description.

In light-emitting device 10d, sealing member 4 includes heat-resistance layer 43 between second sealing layer 42 and main face 2a of mounting board 2. Heat resistance layer 43 is formed of a mixture of particles containing at least one material selected from the group consisting of cerium oxide, titanium oxide, iron oxide, and carbon, and silicone resin. This can suppress generation of a crack in an area of second sealing layer 42 close to mounting board 2. This is assumed that a portion of heat generated in light-emitting element 3 transferred through mounting board 2 is not directly transferred to second sealing layer 42 but to heat resistance layer 43.

In heat resistance layer 43, the average particle size of the particles containing at least one material selected from the group consisting of cerium oxide, titanium oxide, iron oxide, and carbon is preferably 10 μm or less. In addition, the average particle size of the particles is preferably 1 μm or more. In heat resistance layer 43, content of the particles containing at least one material selected from the group consisting of cerium oxide, titanium oxide, iron oxide, and carbon is preferably over 0 wt % and 1 wt % or less. This can suppress excessive decrease in light transmittance of heat resistance layer 43.

Light-emitting devices 10a, 10b, 10c, and 10d can be used as a light source of a range of lighting equipment. Suitable examples of lighting equipment are lighting fixtures in which one of light-emitting devices 10a to 10d is disposed as a light source, and lamps (e.g., straight-tube LED lamps and bulb lamps), but lighting equipment other than these is also applicable.

In light-emitting devices 10a, 10b, 10c, and 10d, the first electrode and the second electrode are provided on the same face of light-emitting element 3. However, this is not limited. The first electrode may be formed on one face of light-emitting element 3, and the second electrode may be formed on the other face.

Furthermore, light-emitting devices 10a, 10b, 10, and 10d adopt LEDs as light-emitting elements 3. However, this is not limited. For example, LD may be adopted.

What is claimed is:

1. A light-emitting device comprising:
a mounting board;
a light-emitting element mounted on a main face of the mounting board; and
a sealing member covering the light-emitting element,
the sealing member includes:
a first sealing layer covering a part of the main face of the mounting board, and the light-emitting element; and
a second sealing layer covering the first sealing layer,
wherein
the first sealing layer includes:
a particle containing at least one material selected from a group consisting of cerium oxide, titanium oxide, iron oxide, and carbon, and
silicone resin, and
the second sealing layer includes:
a phosphor particle for converting a part of light emitted from the light-emitting element into a long wavelength light and radiating it, and
silicone resin.

2. The light-emitting device of claim 1,
wherein
the first sealing layer is formed in a semispherical shape.

3. The light-emitting device of claim 1,
wherein
an average particle size of the particle in the first sealing layer is not less than 1 μm and not greater than 10 μm.

4. The light-emitting device of claim 1,
wherein
the mounting board includes a support formed of a ceramic substrate, and a first conductor and a second conductor, both conductors formed on a main face of the support and electrically connected to the light-emitting element.

5. The light-emitting device of claim 1,
wherein
the mounting board includes a support formed of a metal substrate where an electric insulation layer is formed on its surface, and a first conductor and a second conductor, both conductors formed on the support via the electric insulation layer and electrically connected to the light-emitting element.

6. The light-emitting device of claim 1, further comprising a bonding part for bonding the light-emitting element onto the mounting board,
the bonding part including:
a particle containing at least one selected from a group consisting of cerium oxide, titanium oxide, iron oxide, and carbon, and
silicone resin.

7. The light-emitting device of claim 6,
wherein
an average particle size of the particle in the bonding part is not less than 1 μm and not greater than 10 μm.

8. The light-emitting device of claim 1
wherein
the sealing member includes a heat resistance layer between the second sealing layer and the main face of the mounting board, and
the heat resistance layer includes:
a particle containing at least one selected from a group consisting of cerium oxide, titanium oxide, iron oxide, and carbon, and
silicone resin.

9. The light-emitting device of claim 8,
wherein
an average particle size of the particle in the heat resistance layer is not less than 1 μm and not greater than 10 μm.
